(19) United States
(12) Patent Application Publication
(10) Pub. No.: US 2002/0117399 A1
(43) Pub. Date: Aug. 29, 2002

(54) Atomically thin highly resistive barrier layer in a copper via

(75) Inventors: Fusen Chen, Saratoga, CA (US); Ling Chen, Sunnyvale, CA (US)

Correspondence Address: APPLIED MATERIALS, INC., Patent / Legal Department, P.O. Box 450A, Santa Clara, CA, 95052, US

(73) Assignee: Applied Materials, Inc.

(21) Appl. No.: 09/792,737

(22) Filed: Feb. 23, 2001

(51) Int. Cl. B32B 9/00; H01L 21/283; C25D 5/02; C23C 28/02; C23C 28/00; B32B 27/14; B32B 3/00; B32B 7/00

(52) U.S. Cl. 205/125; 428/209; 428/195; 428/472; 428/336; 428/698; 205/186; 205/188

(57) ABSTRACT

A method of forming a copper via and the resultant structure. A thin layer of an insulating barrier material, such as aluminum oxide or tantalum nitride, is conformally coated onto the sides and bottom of the via hole, for example, by atomic layer deposition (ALD) to a thickness of less than 5 nm, preferably less than 2 nm and having an electrical resistivity of more than 500 microohm-cm. A copper seed layer is then deposited under conditions such that copper is deposited on the via sidewalls but not deposited over most of the bottom of via hole. Instead energetic copper ions sputter the barrier material from the via bottom. Copper is electroplated into the via hole lined only on its sidewalls with the barrier. The invention preferably extends also to dual-damascene structures in which the copper seed sputter process sputters the barrier layer from the via bottom but not the trench floor.

### FIELD OF THE INVENTION

The invention relates generally to barrier layers in via formed in integrated circuits. In particular, the invention relates to an integrated process of forming copper vias.

### BACKGROUND ART

Most semiconductor integrated circuits include several levels of interconnects, also called metallization levels, to electrically interconnect the millions to hundreds of millions of transistors found in advanced integrated circuits. Each metallization level includes a dielectric layer, typically based upon silicon oxide although other, low-k dielectric materials are being pursued. Via holes are etched into the dielectric layer. A metallization material is filled into the via holes to form the vertical interconnects, and the metallization material is further patterned on the top of the dielectric layer to form the horizontal interconnects.

In the recent past, aluminum has been the metallization material of choice. However, copper metallization is becoming increasingly prevalent because of its low resistivity, its reduced electromigration, and the ease of depositing copper with electroplating.

For both aluminum and copper metallization, it has been recognized that the via hole needs to be lined with a barrier layer to prevent the diffusion of the metal atoms of the metallization into the dielectric and of the oxygen atoms of the dielectric into the metallization, both of which may be deleterious. A copper via structure is schematically illustrated in cross-section in FIG. 1 just prior to the chemical mechanical polishing (CMP) step. A lower dielectric layer 10 has a conductive feature 12 formed in or on top of its upper surface. For vias interconnecting two metallization layers, the conductive feature 12 is the copper metallization of the lower layer, composed of either substantially pure copper or an alloy of materials with copper to an alloying percentage of less than 10 wt %. Examples of copper alloying materials include magnesium and aluminum. A contact interconnects the first-level metallization with the underlying silicon substrate. In this case, the conductive feature 12 is associated with a silicon transistor, and the contact is more demanding because of the problem of degrading the semiconductor material. Hereafter, only vias will be referred to, but it is understood that a via is in very similar to a contact and many of the advantages of the invention may be applied to contacts, which will be included in the definition of a via unless specifically stated to the contrary.

A second-level dielectric layer 14 is deposited over both the lower-level dielectric layer 10 and the conductive feature 12. A via hole 16 is etched through the area of the upper dielectric layer 14 overlying the conductive feature 12. A barrier layer 18 is conformally coated onto the etched upper dielectric layer 14 and includes a field portion 20 on top of the dielectric layer 14, a sidewall portion 22 on the vertically extending sidewalls of the via hole 16, and a bottom portion 24 at the bottom of the via 24 over the conductive feature 12. A thin copper seed layer 26 is deposited on the top of the barrier layer 22 to both serve as the electroplating electrode and to seed the growth of the electroplate copper. Electrochemical plating (ECP) fills a via metallization 28 into the lined via hole 16 and over the top of the dielectric layer 14. Although not illustrated, the structure is then subjected to chemical mechanical polishing (CMP) to remove the portion of the copper outside of the via hole 16 and on top of the dielectric layer 14. The remaining copper provides electrical connection through the upper dielectric layer 14 to the conductive feature 12. For dual-damascene structures to be described later the same copper metallization also provides for horizontal interconnects over the upper dielectric layer 14.

For copper metallization, the typical barrier is tantalum and tantalum nitride (Ta/TaN), but titanium and titanium nitride (Ti/TiN) may be used and tungsten and tungsten nitride (W/WN) are also proposed. In all these case for copper metallization, the need for the metal glue layer is uncertain. Of course, more complicated barrier layers based on metal nitrides are possible.

The choice of the barrier material in the typical configuration of FIG. 1 presents countervailing considerations. The various refractory metals, such as Ti, Ta, and W, are of themselves generally unsatisfactory diffusion barriers. The metal nitrides such as TiN, TaN, and WN are adequate diffusion barriers even though their somewhat high electrical resistivities create a problem with the bottom portion 24 of the barrier layer 18 since this portion 24 is interposed in the electrical path between the via metallization 26 and the conductive feature 12. The resistivities of TiN and WN are somewhat less than 500 μΩ-cm while that for TaN grown by chemical vapor deposition (CVD) including atomic layer deposition (ALD) is somewhat greater than 1000 μΩ-cm. The resistivity of TaN grown by physical vapor deposition (PVD) varies from 200 μΩ-cm upwards depending upon the deposition conditions. The barrier layer contributes a substantial portion of the contact resistance between the two metallization layers. On the basis of contact resistance, a high resistance barrier is not considered an optimal choice. At least the nitrides have the advantage of being capable of deposition by conformal deposition into high aspect via holes, for example, having an aspect ratio of at least 5:1 between the depth to the minimum width of the via hole.

Proposals have been made to use oxides such as alumina (Al₂O₃) as the barrier material. While oxide materials may be effective barriers because of their highly ionic bonding, their typically high electrical resistivities create a substantial problem with the contact resistance introduced by an insulating bottom portion 24 of the barrier layer 18.

A further problem with barriers arises because via holes in advanced integrated circuits are very narrow and have very high aspect ratios. Via widths are being reduced to less than 0.18μ, and via widths of 0.10 μm and less are being contemplated. At the same time, the thickness of the inter-level dielectric layers must be maintained at about 0.7 μm and above to prevent inter-level cross-talk and breakdown. It is anticipated that as inter-line and inter-via gaps on the same level decrease, the dielectric thickness will be reduced somewhat to limit the total capacitance determined by the conductor height so that an aspect ratio of about 5:1 seems to be about optimal. Conformal linings in such high aspect-ratio holes can be accomplished by chemical vapor deposition (CVD), and CVD processes are available for most of the available nitride barrier materials and their corresponding refractory metals. However, for very narrow via holes, the lining thickness must be very thin but uniform in order that the barrier both be effective without occupying an undue portion of the via hole so as to reduce the conductive cross section of the after deposited metallization. It has proven difficult to uniformly deposit the any of the low resistivity nitride materials.

Accordingly, it would be useful to not be limited to low-resistivity barrier materials.

Geffken et al. in U.S. Pat. No. 5,985,762 disclose a separate directional etching step to remove the barrier layer from the bottom of the via hole over an underlying copper feature but not from the via sidewalls so that, during the sputter removal of the copper oxide at the via bottom, the dielectric is not poisoned by the sputtered copper. This process requires presumably a separate etching chamber. Furthermore, the process deleteriously also removes the barrier at the bottom of the trench in a dual-damascene structure. They accordingly deposit another conformal barrier layer, which remains under the metallized via so that the barrier contact resistance remains a problem.

### SUMMARY OF THE INVENTION

The invention includes a method of forming a copper via in a dielectric layer and the resultant via structure. An insulating barrier is coated onto the sides and bottom of the via hole. The deposition conditions for sputter depositing a copper seed layer are selected such that the copper is deposited on the sides of the via but, not only is no copper deposited on the via bottom, instead the energetic copper ions sputter the insulating barrier from the via bottom and may additionally etch an underlying copper feature. Copper is filled into the remainder of the via hole by electroplating.

The material of the insulating barrier preferably has an electrical resistivity of at least 500 microohm-cm. One class of such insulating materials are refractory metal oxides, for example, Al₂O₃, Ta₂O₅, W₂O₃, and TiO₂. Other highly resistive materials includes metal nitrides, such as TaN, which has a relatively high resistivity.

The insulating barrier layers are preferably deposited to thicknesses on the sidewalls of no more than 5 nm and more preferably no more than 2 nm. The thickness is preferably more than 0.5 nm. Uniform oxide films of such thinness may be formed by atomic layer deposition using thermal chemical vapor deposition in which a repetitive series of alternating steps of admitting an oxygen precursor, such as water, into the chamber and then, after purging the chamber, of admitting a metal precursor. For nitride films such as TaN, nitrogen or ammonia is admitted in one step and a metal precursor admitted in the other step. Oxygen or nitrogen or the metal deposits, for example, by chemabsorption, to a thickness of about one atomic layer. Preferably, the reaction occurs at the surface and not in the vapor.

The via structure may be a more complex dual-damascene structure in which a via hole at the bottom of the dielectric layer is linked to a larger longitudinally extending trench hole at the top of the dielectric layer. Most preferably the barrier layer is etched only from the bottom of the via hole and not from the floor of the trench.

The selective etching at the bottom of the via hole may be accomplished by selecting a relatively high ionization for the copper atoms and biasing the pedestal electrode supporting the substrate. Selective sputter deposition on more exposed horizontal surfaces may be accomplished by maintaining a finite neutral copper component. The ionization fraction may be increased by increasing the target power. Reduced chamber pressure also enhances via bottom sputtering.

A second seed layer may be deposited at lower ionization fraction or lower pedestal bias so as to coat the copper seed layer on horizontally extending surfaces.

Such processes may be accomplished in a plasma sputter reactor having a vault-shaped target in which one set of magnets are disposed substantially uniformly in back of the vault sidewall and another set of small nested opposed magnets are disposed over the vault roof and are scanned about its circumference.

### BRIEF DESCRIPTION OF THE DRAWINGS

FIG. 1 is a cross-sectional view of a copper via of the prior art.

FIGS. 2 through 5 are cross-sectional view illustrating the formation of one embodiment of a copper via of the invention.

FIG. 6 is a cross-sectional view of a dual-damascene structure according to another embodiment of the invention.

FIG. 7 is a schematic cross-sectional view of a plasma sputter reactor which may be used to practice the invention.

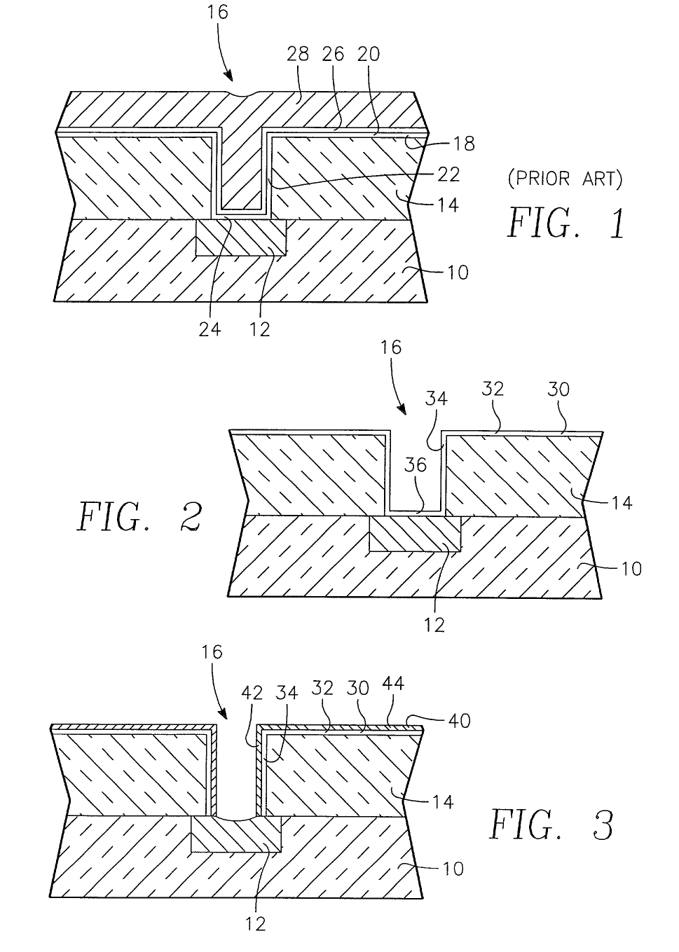

### DETAILED DESCRIPTION OF THE PREFERRED EMBODIMENTS

The invention includes two related aspects. The barrier is composed of a highly resistive material, for example, having an electrical resistivity of greater than 500 microolun-cm (500 μΩ-cm), preferably greater than 1000 microohm-cm. Such highly resistive materials particularly include metal oxides, but tantalum nitride manifests some of the novel features of the invention. The barrier layer is conformally coated onto the sidewalls and bottom of the via hole intended for copper metallization. The deposition of the barrier advantageously employs atomic layer deposition (ALD) in which atomic monolayers of the barrier material are sequentially deposited. A copper seed layer is then sputter deposited under conditions of a medium to high copper ionization level with bias voltage applied to the substrate such that the copper ions sputter the barrier layer at the bottom of the via but deposit the seed layer on the sidewalls of the via. Thereafter, copper is filled into the via hole, preferably by a process including electrochemical plating (ECP), that is, electroplating.

In a first step of forming an inter-level via, as illustrated in the cross-sectional view of FIG. 2, the via hole 16 is etched through the upper dielectric layer 14. A very thin, highly resistive barrier layer 30 is conformally deposited to form a field portion 32 horizontally extending on top of the upper dielectric layer 14, a sidewall portion 34 vertically extending on the sidewalls of the via hole 16, and a bottom portion 36 horizontally extending on the bottom of the via hole 16. One example of the material of the highly insulating barrier is alumina (Al₂O₃). A glue layer, for example, of aluminum may be interposed between the alumina barrier layer and the dielectric. However, in the case of oxide dielectrics, an oxide barrier layer more easily bonds to the dielectric than do nitride barrier materials, thus reducing the need for a glue layer.

Nitride barrier materials are related to oxide barrier materials. Both have strongly ionic bonding between the metal and a cation. The oxide is more ionic, and oxide materials are generally more resistive. Tantalum nitride (TaN) is a commonly used barrier for copper vias, though in thicker layers than contemplated by the invention. CVD TaN and particularly atomic layer deposited TaN are preferred for the TaN barrier.

The highly insulating barrier layer 30 preferably has a thickness of less than 5 nm, and preferably less than 2 nm. A preferred minimum thickness is 0.5 nm The Al—O bonding length is about 0.2 nm so that these thicknesses correspond to about two cubic lattice spacings. Alumina generally grows according to the described methods in an amorphous form, but the crystal bonding and bonding lengths are substantially the same as a would result from a crystalline alumina structure. The amorphous form of the thin barrier layer is preferred because it more readily prevents copper diffusion.

Such very thin layers of metal oxides and nitrides can be grown by atomic layer deposition (ALD), which is a form of CVD, in which monolayers of oxygen or nitrogen and the metal (aluminum in the primary example) are alternately deposited. In a general ALD formation of the compound AB, the A and B components are separately introduced into the reactor and separately condense or are chem-absorbed on the substrate. Once the A component has been chem-absorbed, the chamber is purged of the A component and the B component is introduced into the chamber. The B component then reacts at the substrate surface with the A component to create approximately a single layer of the AB compound. Thereafter, the chamber is purged of the B component, and the process is repeated for another layer of AB. The purging may include injecting a neutral and chemically inactive purge gas such as argon to sweep any reactants out of the system.

Atomic layer deposition is considered chemical vapor deposition (CVD) and is typically a thermal process performed at relatively low temperatures of 120 to 300° C. or even lower. The reaction is a surface reaction, and the sequential process minimizes any gas-phase reaction since the two components are not intended to be present in gas phase at any one time. For Al₂O₃, the oxygen precursor may be water vapor (H₂O), and the aluminum precursor is preferably dimethyl aluminum hydride ((CH₄)₂AlH or DMAH), which decomposes at 170° C. so that the reaction needs to carried out at less than this temperature. For TaN, the nitrogen precursor may be nitrogen gas (N₂) or ammonia (NH₃) and the tantalum precursor may be pentakis (ethylmethylamino) tantalum (PEMAT). A tantalum glue layer may be required between the TaN and the dielectric, which is often based on an oxide such as silica or silicate glass or other, low-k variants.

Atomic layer deposition provides a very conformal coating even at the bottom of very narrow, high aspect-ratio holes since the reactant is not depleted from the gas phase. Because of the atomic-layer control, the thicknesses can be controlled to very thin thicknesses with uniformity better than 1 or 2% about the mean thickness. The low-temperature reactions produce an amorphous material with no detectible long range order over lengths on the order of the film thickness.

Thereafter, as illustrated in the cross-sectional view of FIG. 3, a thin copper seed layer 40 is sputter deposited under conditions such that the copper deposits only as a sidewall portion 42 vertically extending on the sidewall of the via 16 and as a field portion 44 horizontally extend over the top of substrate. However, the conditions of the sputtering of the copper seed level are set such that the energetic copper ions etch away the bottom portion 36 of the barrier layer 30 and further etch a small distance into the underlying copper feature 12. The sidewalls 42 deposit to a moderate thickness because they are protected from the anisotropic flux of the copper ions accelerated by the negatively biased substrate while the via bottom is exposed to the energetic copper ion flux, which not only does not deposit but itself sputters the bottom barrier portion 36. Further, the energetic copper ions tend to be neutralized and reduced in energy upon striking the via bottom and to redeposit on the via sidewall, thus enhancing sidewall coverage. It is noted that the bottom etching of the underlying copper feature 12 is effective at removing any oxide or residue which has developed on its surface. As a result, it may be possible to forego the pre-clean step prior to the copper seed or barrier sputter.

Alternatively, in simple geometries, it is possible to use a separate step prior to the copper seed sputter deposition of directional etching or sputtering to remove the bottom portion 36 of the barrier layer 30 while leaving the sidewall portion 42. This process however typically also removes the field portion 44.

Following the deposition of the copper seed layer, electrochemical plating (ECP) is used, as illustrated in the cross-sectional view of FIG. 4, to deposit a copper layer 50 which fills copper into the via hole 26 and coats copper over the field area atop the substrate. In the ECP step, the copper seed layer 40 is used as a plating electrode. For damascene processes, the copper electroplating is followed by chemical mechanical polishing (CMP), which may stop on the harder insulative barrier layer 30 or on the dielectric layer 12, as illustrated in FIG. 5.

The copper deposition and lack of barrier sputtering in the field area on top of the substrate is a closer, balanced situation. The high-energy copper ions tend to sputter rather than to deposit, but, if there is a substantial component of neutral copper ions, they are not accelerated by the biased substrate and hence tend to deposit on rather than sputter the field area. On the other hand, the bottom of the via hole is shielded from the neutral copper atoms because of its high aspect ratio so they do not deposit on the via bottom. The parameters are preferably adjusted so that the via bottom is sputtered but there is a net though small deposition on the field area. An alternative approach described below is based on no net deposition in the field area. Golpalraja et al. have disclosed a similar process but applied to nitride barriers in U.S. patent application Ser. No. 09/703,601, filed Nov. 1, 2000 in the name of Gopalraja et al. This application is incorporated herein by reference in its entirety. Chen et al. have also described a somewhat similar process using a sputter deposition of a second barrier layer in U.S. patent application Ser. No. 09/704,161, filed Nov. 1, 2000.

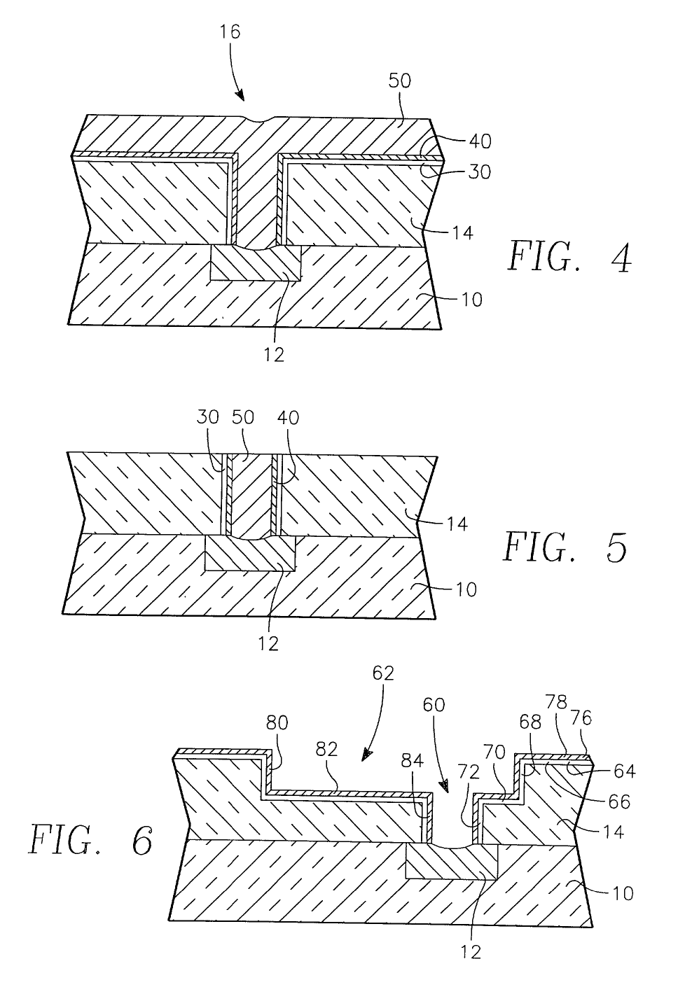

A more difficult geometry is a dual-damascene structure illustrated in the cross-sectional view of FIG. 6 used both to contact the underlying conductive feature 12 and to provide horizontal electrical connections on top of the upper dielectric layer 14. The upper dielectric layer 14 is etched to include one or more vias 60 extending down to respective ones of the conductive feature 12. A wide trench 62 is also etched into the upper dielectric layer 14 to connect different ones of the conductive features 12 or to provide a horizontal interconnection contacted to a different area of the next wiring level.

Following the etching of the upper dielectric layer 14, an oxide barrier layer 64 is deposited to conformally coat the entire structure including a barrier field portion 66, a barrier trench sidewall portion 68, a barrier trench floor portion 70, a barrier via sidewall portion 72, and an unillustrated barrier via bottom portion. Thereafter, a copper seed layer 76 is sputter deposited under conditions that it deposits as a seed field portion 78, a seed trench sidewall portion 80, a seed trench floor portion 82, and a seed via sidewall portion 84. Importantly, the seed sputter process does not deposit copper on the bottom of the via 60. Instead, it sputters away the portion of the barrier layer at the bottom of the via 60 and slightly etches into the underlying conductive feature. Preferably, the seed sputter conditions are set so that seed sputter process deposits copper layers 78, 82 in the field area and the trench floor rather than removing the barrier portions 66, 70 there. Similarly to the situation with the simple via of FIG. 3, only the energetic copper ions reach the bottom of via 60 to sputter the barrier rather than to deposit as copper, and the field area is subjected to a significant flux of lower energy copper neutrals. The trench floor presents an intermediate geometry. Trenches extend for significant distances and thus have very high aspect ratios along their axial directions. However, in the transverse direction, they are only somewhat wider than vias, for example, by a factor of 2 or 3. As a result, their effective aspect ratios for differentiating energetic copper ions and unenergetic copper neutrals present a geometry intermediate the via bottom and the field area, thus allowing the different balance of sputtering and deposition between the trench floor and the via bottom.

However, it is also possible that the trench floor or even the field area is sputtered but then to perform a second, less ionized or less energetic seed sputter step to coat those horizontally extending areas. The second sputter step is also advantageous if the seed layer is deposited only thinly there so that a thicker and more reliable seed layer is deposited. Of course, this multi-step sputtering is also applicable to the nitride barrier materials.

The above described process combines the removal bottom barrier with the copper seed deposition. However, it is possible to remove the bottom barrier by other methods such as a highly directional etch and to thereafter deposit the copper seed. An argon sputter etch would suffice for removing the bottom barrier although it would also remove the barrier in the field and trench floor areas.

Materials other than alumina may be used for forming the insulating barrier of the invention. Many metal oxides are electrically insulating and can be grown by atomic layer deposition. Examples are tantalum oxide (Ta₂O₅), tungsten oxide (W₂O₃) and titanium oxide (TiO₂). Other oxides of the refractory metals of Groups IVB, VB, and VIB of the periodic table can provide similarly good results Ti, Ta, and W of these same groups. Further, tantalum nitride, although not an oxide, has a relatively high electrical resistance and can also benefit from the invention. Other nitrides of the above listed refractory metals can be expected to provide good results, especially in view of the use of some of them as barrier materials, though in thicker layers.

The sputtering processes described above require a sputter reactor which can control the energy of ions incident on the substrate and which preferably can finely control the ionization fraction of sputter metal atoms. Some features of the invention can be achieved using a high-density plasma sputter reactor, such as on relying on RF inductive coupling to create a high-density plasma of the argon working gas. Such a reactor is effective at removing the oxide barrier layer at the bottom of the via. However, a preferred reactor is the SIP⁺ plasma sputter reactor described in the above cited patent application Ser. No. 09/703,601 to Gopalraja et al. This reactor produces a high ionization fraction of sputtered metal atoms, particularly of copper, so that a sufficient number of the metal ions sputtered from the target are attracted back to the target to resputter the target. As a result, the pressure of the argon working gas can be considerably reduced, and in some situations no working gas is required to continue sputtering. This process produces a self-ionized plasma (SIP).

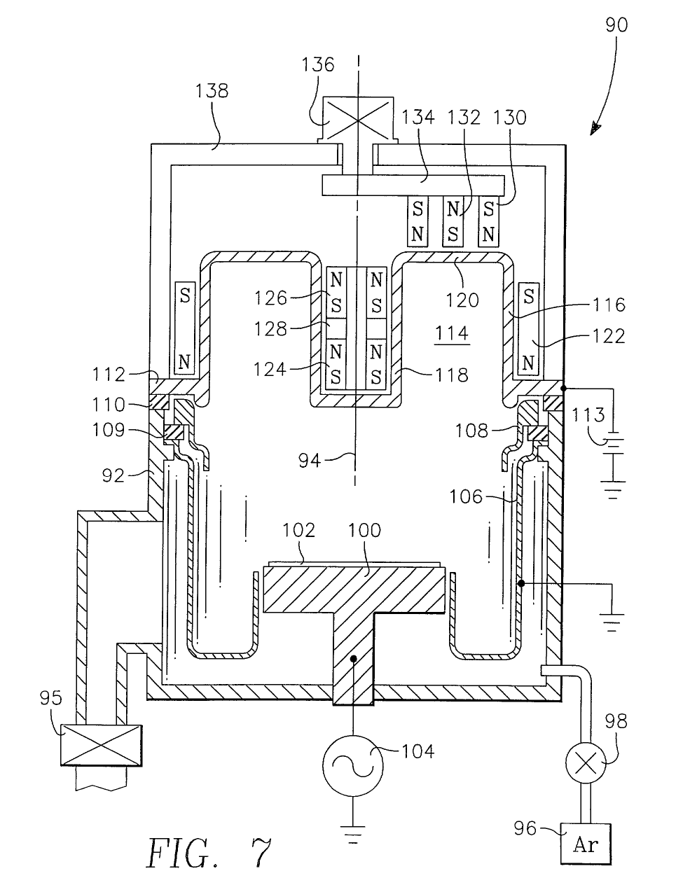

An example of an SIP⁺ plasma sputter reactor 90 is schematically illustrated in cross section in FIG. 7. More details are found in the above cited patent application Ser. No. 09/703,601 to Gopalraja et al. and in U.S. patent application Ser. No. 09/703,738, filed Nov. 1, 2000 by Subramani et al. The lower portion of the reactor 90 is modified from a fairly conventional sputter reactor including a lower vacuum chamber 92 arranged around a central axis 94 and pumped by a vacuum system 95. A working gas such as argon is supplied as needed from a gas source 96 through a mass flow controller 98. A pedestal electrode 100 supports a substrate (wafer) 102 to be sputter deposited and is biased by an RF electrical source 104. A grounded shield 106 protects the chamber walls from deposition and acts as anode to the biased sputter target. An electrically floating shield 108 supported on an isolator 109 is useful to focus and direct the ionized sputter particles to the wafer 102.

An isolator 110 supports a novel vault-shaped sputter target 112 on the chamber 92. For copper sputtering, the target 112 is composed of copper or a copper alloy. A power supply 113 biases the target 112 to a negative DC voltage to excite and maintain the sputtering plasma. The vault-shaped target 112 includes an annular vault 114 extending around the central axis 94 and facing the wafer 102. The vault includes an outer sidewall 116, an inner sidewall 118, and a roof 120.

The magnetron includes two parts. A first magnetron part that is effectively stationary for purposes of this invention includes a tubularly arranged outer magnet 122 of a first vertical magnetic polarity disposed in back of the outer target sidewall 116 and a pair of tubular inner magnets 124, 126 of a second and opposite vertical magnetic polarity disposed in back of the inner target sidewall 118 and separated by a non-magnetic spacer 128. The first magnetron part creates a magnetic field that extends uniformly around the circumference of the vault 114.

A second magnetron part disposed in back of the target roof 120 includes an outer tubular magnet 130 of the first vertical magnetic polarity surrounding a rod magnet 132 of the second vertical magnetic polarity. Preferably, the outer magnet 130 has a total magnetic flux that is at least 50% greater than that of the inner magnet 132. A magnetic yoke 134 magnetically couples the roof magnets 130, 132. The generally circularly symmetric roof magnets 130, 132 have a lateral extent approximately equal to that of the vault roof 120. As a result, the magnetic field it produces is localized in a restricted circumferential area of the vault 114. However, the magnetic yoke 134 of the roof magnets 130, 132 is connected to a motor 136 mounted on an upper back chamber 138 which rotates the roof magnets 130, 132 around the vault circumference and about the central axis 94, thereby providing a uniform sputter distribution over time.

The plasma reactor 90 is observed to operate in two sputter modes. We believe, although the invention is not constrained by this belief, that the two modes arise from whether the sputtering plasma is maintained only in the area of the vault 114 beneath the rotating roof magnets 130, 132 or whether the plasma extends completely around the annular vault 114. The portion of the plasma beneath the roof magnets 130, 132 produces a high fraction of ionized copper atoms while any portion of the plasma away located at a distance from the roof magnets 130, 132 produces relatively more neutral copper ions. A higher copper ionization fraction is observed with increased target power and with decreased chamber pressure. The SIP⁺ reactor 90 creates a very high magnetic field in the area of the vault adjacent the roof magnets 130, 132. Therefore, it can support a plasma at relatively low chamber pressures of 0.2 milliTorr and below. Indeed, at sufficiently high target power for copper sputtering, a sufficient number of copper ions are generated to substitute for the sputtering ions of the argon working gas, and the supply of argon may be turned of once the plasma is ignited in a process called sustained self-sputtering (SSS).

The energy of the positively charged copper ions incident upon the wafer 102 is increased by increasing the RF bias power supplied to the pedestal electrode 100 because of the increasing negative DC self-bias. The three parameters controlling the selective deposition and sputtering of the invention are the target power, the chamber pressure, and the bias power, as has been explained by both Gopalraj a et al. and Chen et al. in the aforementioned patent applications.

Thus, several developing technologies can be usefully combined to allow the use of highly resistive barrier layers in copper vias of very narrow widths and without unduly complicating the overall process.

1. A process of filling copper into a vertical interconnection hole extending through an inter-level dielectric layer formed in a substrate and having sides and a bottom, comprising the steps of:
coating sides and a bottom of said hole with a barrier layer of a metal oxide or nitride having an electrical resistivity greater than 500 microohm-cm;
sputtering a copper target opposed to said substrate under conditions such that a copper layer is deposited on said sides of said hole while simultaneously said barrier layer is removed from said bottom of said hole; and
then electroplating copper into said hole.

2. The process of claim 1, wherein said coating step comprises atomic layer deposition.

3. The process of claim 2, wherein said coating step alternately and repetitively deposits from respective chemical precursors a metal portion of said metal oxide and an oxygen portion of said metal oxide.

4. The process of claim 2, wherein said coating step alternately and repetitively deposits from respective chemical precursors a metal portion of said metal nitride and a nitrogen portion of said metal nitride.

5. The process of claim 1, wherein said barrier layer has a thickness on said sides of no more than 5 nm.

6. The process of claim 5, wherein said thickness is no more than 2 nm.

7. The process of claim 6, wherein said thickness is at least 0.5 nm.

8. The process of claim 1, wherein said barrier layer comprises a metal oxide.

9. The process of claim 8, wherein said metal oxide comprises an oxide of a refractory metal chosen from Groups IVB, VB, and VIB of the periodic table.

10. The process of claim 9, wherein said metal oxide comprises aluminum oxide.

11. The process of claim 1, wherein said barrier layer comprises tantalum nitride.

12. A process of filling copper into a vertical interconnection hole extending through an inter-level dielectric layer formed in a substrate and having sides and a bottom, comprising the steps of:
coating sides and a bottom of said hole with a barrier layer of a metal oxide or nitride having an electrical resistivity greater than 500 microohm-cm and a thickness on said sides of less than 5 nm;
removing said barrier layer from said bottom;
sputtering a copper target opposed to said substrate to deposit a copper layer on at least said sides; and
then electroplating copper into said hole.

13. The process of claim 12, wherein said resistivity is greater than 1000 micro ohm-cm.

14. The process of claim 12, wherein said thickness is no more than 2 nm.

15. The process of claim 14, wherein said thickness is at least 0.5 nm.

16. The process of claim 16, wherein said barrier layer comprises an oxide of a refractory metal chosen from Groups IVB, VB, and VIB of the periodic table.

17. The process of claim 16, wherein said oxide comprises aluminum oxide.

18. The process of claim 12, wherein said barrier layer comprises tantalum nitride.

19. A copper via structure, comprising:
a lower dielectric layer having a copper feature formed in its surface;
an upper dielectric layer formed over said lower dielectric layer and having a hole formed therethrough in an area of said copper feature;
a barrier layer comprising a metal oxide formed on sides of said hole but not on a bottom of said hole facing said copper feature; and
copper filled into said hole and contacting said copper feature.

20. The copper via structure of claim 19, wherein said oxide barrier layer comprises an oxide of a refractory metal chosen from Groups IVB, VB, and VIB of the periodic table.

21. The copper via structure of claim 20, wherein said oxide barrier layer comprises aluminum oxide.

22 The copper via structure of claim 19, wherein said barrier layer has a thickness on said sides of said hole of no more than 5 nm.

23. The copper via structure of claim 22, wherein said thickness is no more than 2 nm.

24. The copper via structure of claim 25, wherein said thickness is at least 0.5 nm.

25. A copper via structure, comprising:
a lower dielectric layer having a copper feature formed in its surface;
an upper dielectric layer formed over said lower dielectric layer and having a hole formed therethrough in an area of said copper feature;
a barrier layer comprising a metal oxide or nitride formed on sides of said hole to a thickness of no more than 5 nm but not on a bottom of said hole facing said copper feature; and
copper filled into said hole and contacting said copper feature.

26. The copper via structure of claim 25, wherein said thickness is no more than 2 nm.

27. The copper via structure of claim 26, wherein said thickness is no more than 0.5 nm.

28. The copper via structure of claim 25, wherein said barrier layer comprises a metal oxide.

29. The copper via structure of claim 28, wherein said metal oxide comprises aluminum oxide.

30. The copper via structure of claim 25, wherein said barrier layer comprises a metal nitride.

31. The copper via structure of claim 30, wherein said metal nitride comprises tantalum nitride.

32. A copper via structure, comprising:
a lower dielectric layer having a conductive feature formed in its surface;
an upper dielectric layer formed over said lower dielectric layer and having a hole formed therethrough in an area of said conductive feature;
a barrier layer comprising tantalum nitride formed on sides of said hole to a thickness of greater than 0.5 nm and no more than 5 nm but not on a bottom of said hole facing said conductive feature; and
copper filled into said hole.

33. The copper via structure of claim 32, wherein said thickness is no more than 2 nm.
